(19) United States
(12) Patent Application Publication
(10) Pub. No.: US 2007/0087272 A1
(43) Pub. Date: Apr. 19, 2007

(54) Method for preparing a phase-shifting mask and method for preparing a semiconductor device using the phase-shifting mask

(75) Inventor: Yee Kai Lai, Jungli City (CN)

Correspondence Address: OLIFF & BERRIDGE, PLC, P.O. BOX 19928, ALEXANDRIA, VA, 22320, US

(73) Assignee: Promos Technologies Inc., Hsinchu (CN)

(21) Appl. No.: 11/283,723

(22) Filed: Nov. 22, 2005

(30) Foreign Application Priority Data
Oct. 13, 2005 (TW) 094135647

(51) Int. Cl. G03C 5/00; G03F 9/00; G03F 1/00

(52) U.S. Cl. 430/5; 430/22; 430/322; 430/323

(57) ABSTRACT

A phase-shifting mask comprises a substrate and a plurality of phase-shifting patterns made of polymer material and positioned on the substrate in an array manner. Preferably, the space between phase-shifting patterns is smaller than the width of the phase-shifting pattern along a first direction, and the space between two line-shaped patterns consisting of phase-shifting patterns is substantially equal to the width of the line-shaped pattern along a second direction perpendicular to the first direction. The present method for preparing the phase-shifting mask comprises steps of forming a polymer layer on a substrate, changing the molecular structure the polymer layer in a plurality of predetermined regions, and removing a portion of the polymer layer outside these predetermined regions. The polymer layer can be made of hydrogen silsesquioxane, methylsilsesquioxane or hybrid organic siloxane polymer.

### BACKGROUND OF THE INVENTION

(A) Field of the Invention

The present invention relates to a method for preparing a phase-shifting mask and a method for preparing a semiconductor device using the phase-shifting mask, and more particularly, to a method for preparing a phase-shifting mask having phase-shifting patterns made of polymer material and a method for preparing a semiconductor device using the phase-shifting mask.

(B) Description of the Related Art

As the integration density of semiconductor devices increases, the lithographic process needs a higher resolution to meet the precision requirement of the semiconductor device. One method to increase resolution is to use a light source with a shorter wavelength as the exposure light. For example, the krypton fluoride (KrF) laser is used to provide deep UV light with a wavelength of 248 nanometers, and the argon fluoride (ArF) laser is used to provide deep UV light with a wavelength of 193 nanometers. Another method for increasing the resolution is to use a phase-shifting mask. This solution can increase lithographic resolution without changing the exposure light, and therefore has become an important technique developed by the semiconductor industry.

FIG. 1 to FIG. 5 illustrate a method for preparing a chromeless phase-shifting mask 10 disclosed in U.S. Pat. No. 5,240,796. The conventional method first deposits a chromium layer 22 on a quartz substrate 20, and a lithographic process is then performed to form a photoresist layer 24 including a plurality of opening patterns on the chromium layer 22. An etching process is performed to remove a portion of the chromium layer 22 not covered by the photoresist layer 24 down to the surface of the quartz substrate 20 to form a plurality of opening patterns 26 in the chromium layer 22, and a stripping process is then performed to remove the photoresist layer 24 completely, as shown in FIG. 2.

Referring to FIG. 3, the chromium layer 22 is used as an etching mask, and another etching process is performed to remove a portion of the quartz substrate 20 not covered by the chromium layer 22 down to a predetermined depth “T” to form a plurality of opening patterns 32 in the quartz substrate 20. Subsequently, another lithographic process is performed to form a photoresist layer 28 on the chromium layer 22, and another etching process is performed to remove a portion of the chromium layer 22 not covered by the photoresist layer 28 down to the surface of the quartz substrate 20 to form a plurality of scattering bars 30, i.e., assistant features, as shown in FIG. 4. Finally, another stripping process is performed to remove the photoresist layer 28 to complete the chromeless phase-shifting mask 10, as shown in FIG. 5. Particularly, a plurality of protrusions 34 are formed on the surface of the quartz substrate 20 between the opening patterns 32.

FIG. 6 is a schematic diagram showing the application of the chromeless phase-shifting mask 10 to exposing a photoresist layer (not shown in the figure) by an exposure light 12 according to the prior art. Due to the varying thickness of the quartz substrate 20, the phase-shifting angle of the penetrating light 14 is different from that of the penetrating light 16, by which interference occurs. The difference of the propagation distance in the quartz substrate 20 between the penetrating light 14 and the penetrating light 16 is: Δd=d₁−d₂=mλ/└2(n_{quartz}−nₐᵢᵣ)┘, where n represents the refractive index, λ represent the wavelength of the exposure light 12, and m represents a positive integer. Theoretically, the phase-shifting angle of the penetrating light 14 is designed to lag 180 degrees behind that of the penetrating light 16, i.e., the protrusions 34 are used as phase-shifting patterns, to generate a destructive interference to increase the lithographic resolution.

However, the depth of the opening pattern 32 generated by the etching process is difficult to control exactly to the predetermined depth “T” since the etching process cannot be controlled precisely. In addition, it is quite difficult to precisely control the profile of sidewalls and the size of the opening pattern 32 by the etching process, which tends to generate a trapezoidal opening rather than the desired rectangular opening. In other words, it is difficult to control the depth, profile and size of the opening pattern 32, and the phase-shifting angle between the penetrating light 14 and the penetrating light 16 is not the theoretical value, 180 degrees. Consequently, a phase error will occur.

In addition, the prior art prepares the opening patterns 32 by etching the quartz substrate 20, but quartz contamination defects are likely to form around the opening patterns 32, which increase the difficulty of mask inspection. Further, the prior art needs to perform the lithographic process twice to form the patterned photoresist layers 24 and 28, which not only increases the difficulty for alignment but also restrict mask throughput. Particularly, the off-axis illumination (OAI) technique, widely used in advanced semiconductor fabrication, cannot prepare an image if the line width and space width on the phase-shifting mask are of equal size, i.e., line width: space width is 1:1.

### SUMMARY OF THE INVENTION

The primary objective of the present invention is to provide a method for preparing a phase-shifting mask having phase-shifting patterns made of polymer material and a method for preparing a semiconductor device using the phase-shifting mask, which can increase mask throughput, eliminate the phase error problem and mask inspection issue, and solve the imaging problem of the OAI technique in cases where masks have equal line width and space width.

In order to achieve the above-mentioned objective and avoid the problems of the prior art, one embodiment of the present invention discloses a method for preparing a phase-shifting mask comprises steps of forming a polymer layer on a substrate, changing the molecular structure of the polymer layer in a plurality of predetermined regions, and removing a portion of the polymer layer outside the predetermined regions to form a plurality of phase-shifting patterns. The polymer layer can include hydrogen silsesquioxane (HSQ), and a developing process using an alkaline solution is performed to remove the polymer layer outside the predetermined region, wherein the alkaline solution is selected from the group consisting of sodium hydroxide (NaOH), potassium hydroxide (KOH) and tetramethylamomnium hydroxide (TMAH). In addition, the polymer layer can include methylsilsesquioxane (MSQ), and a developing process using an alcohol solution such as an ethanol solution is performed to remove the polymer layer outside the predetermined region. Further, the polymer layer can include hybrid organic siloxane polymer (HOSP), and a developing process using a propyl acetate solution is performed to remove the polymer layer outside the predetermined region.

Compared to the prior art, the present invention can increase mask throughput, eliminate phase error problems and mask inspection issues, and solve the imaging limitation of the OAI technique in cases where masks have equal line and space width.
1. The prior art needs to perform the lithographic process twice, which increases the alignment difficulty and restricts the mask throughput. On the contrary, the present method is simpler since the phase-shifting pattern is prepared by the integration of the coating (or deposition) technique, the electron beam exposure technique and the lithographic process, without an etching process so mask throughput can be increased. Further, the present method does not need to perform the lithographic process twice to prepare the phase-shifting pattern, so there are no alignment issues.
2. The prior art prepares the phase-shifting pattern by etching the quartz substrate, which generates issues of mask inspection and phase error. On the contrary, the present method prepares the phase-shifting pattern without etching the substrate, so the phase error problem and the mask inspection issue can be eliminated.
3. The present invention can solve the imaging problem of the OAI technique in cases where the phase-shifting mask has equal line width and space width, i.e., line width: space width is 1:1, and thereby increase the contrast of patterns.

### BRIEF DESCRIPTION OF THE DRAWINGS

The objectives and advantages of the present invention will become apparent upon reading the following description and upon reference to the accompanying drawings in which:

FIG. 1 to FIG. 5 illustrate a method for preparing a chromeless phase-shifting mask according to the prior art;

FIG. 6 is a schematic diagram showing the application of a chromeless phase-shifting mask to expose a photoresist layer according to the prior art;

FIG. 7 to FIG. 9 illustrates a method for preparing a chromeless phase-shifting mask according to one embodiment of the present invention;

FIG. 10 is a diagram showing the variation of the reflection index of the phase-shifting pattern under different wavelengths according to the present invention;

FIG. 11 is a diagram showing the variation of the extinction coefficient of the phase-shifting pattern under different wavelengths according to the present invention;

FIG. 12 and FIG. 13 are schematic diagrams showing the application of the phase-shifting mask to pattern a semiconductor device on a semiconductor substrate according to one embodiment of the present invention;

FIG. 14(a) shows the intensity distribution of an aerial image after an exposure light penetrates through the chromeless phase-shifting mask according to the present invention; and

FIG. 14(b) shows the intensity distribution of an aerial image after an exposure light penetrates through the chromeless phase-shifting mask according to the prior art.

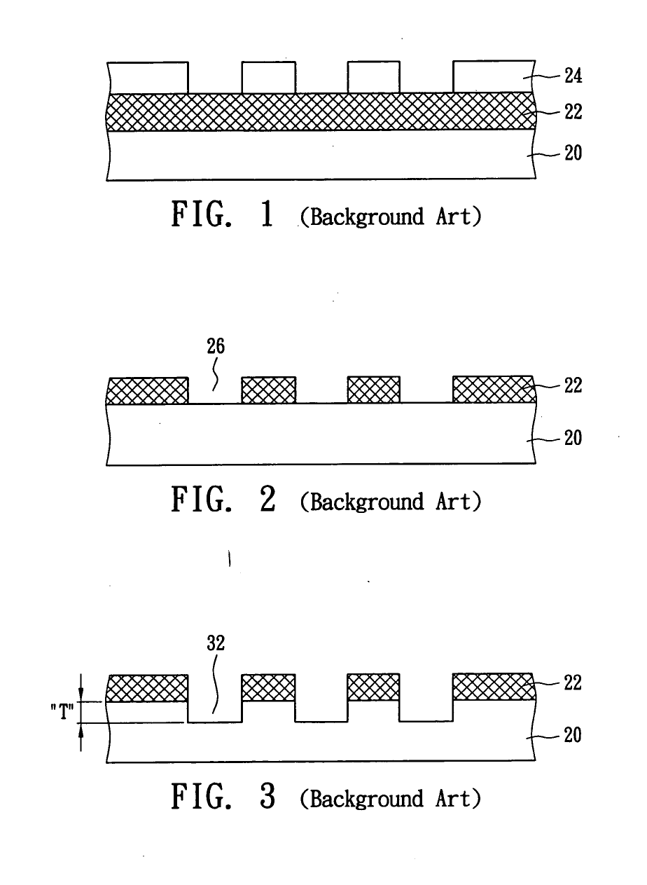

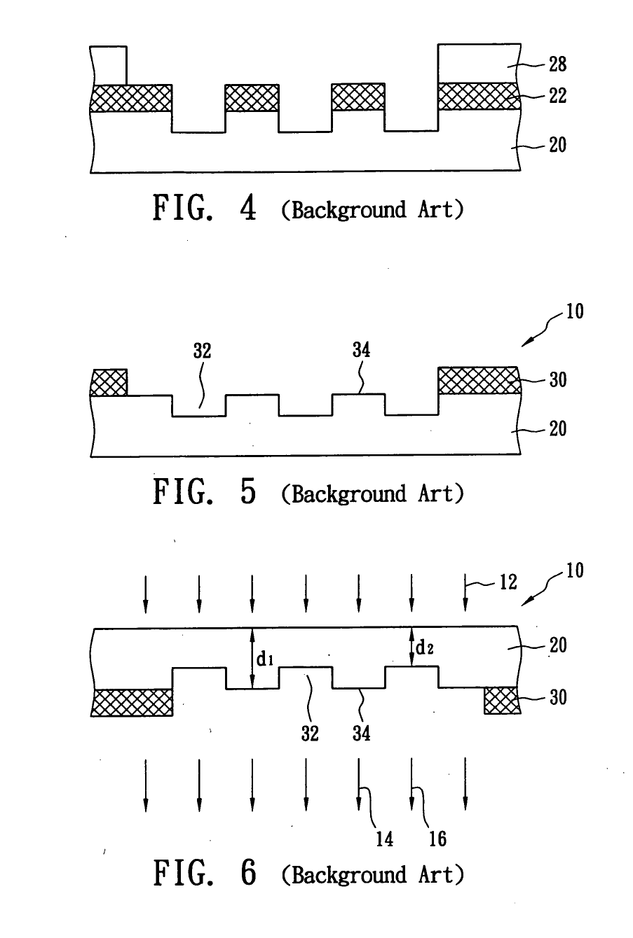

### DETAILED DESCRIPTION OF THE INVENTION

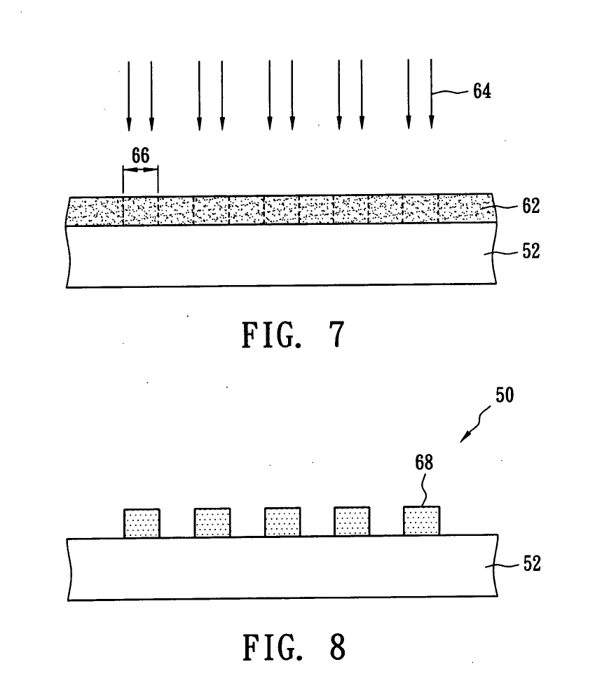

FIG. 7 to FIG. 9 illustrate a method for preparing a chromeless phase-shifting mask 50 according to one embodiment of the present invention. A spin-coating process is performed to form a polymer layer 62 on a substrate 52, and energy is then selectively transferred to a portion of the polymer layer 62 in a plurality of predetermined regions 66 arranged in an array manner, such as irradiating an electron beam 64 to the predetermined region 66, to change the chemical properties of the polymer layer 62 in the predetermined region 66, i.e., to change the molecular structure of the polymer layer 62 in the predetermined regions 66. Particularly, the electron beam 64 provides energy to activate the polymer in the predetermined region 66 to change its molecular structure such as forming cross-linking.

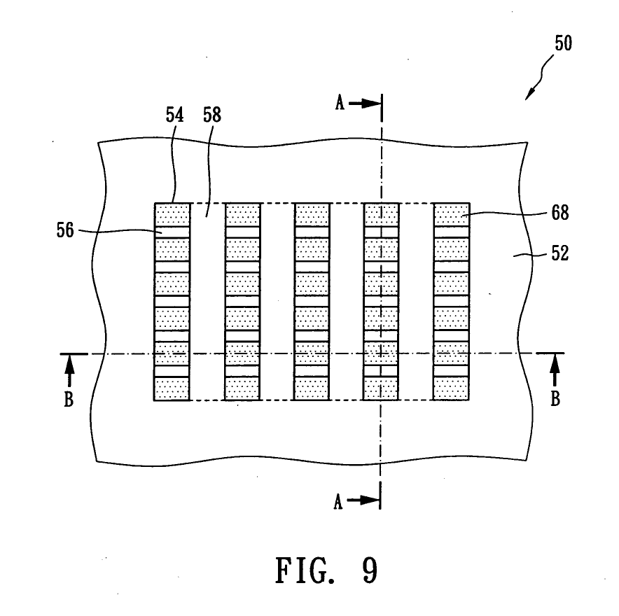

Referring to FIG. 8, a developing process is performed to remove a portion of the polymer layer 62 not irradiated by the electron beam 64, i.e., the polymer layer 62 outside the predetermined region 66, while the polymer layer 62 in the predetermined region 66 remains to form a plurality of phase-shifting patterns 68 in an array manner on the substrate 52, as shown in FIG. 9. Since the electron beam 64 provides energy for the polymer to change the molecular structure, the solubility to a developer of the polymer irradiated by the electron beam 64 is different from that of the polymer not irradiated by the electron beam 64. Consequently, the developing process can selectively remove the portion of the polymer layer 62 not irradiated by the electron beam 64, i.e., remove the portion of the polymer layer 62 outside the predetermined region 66, while maintaining the other portion of the polymer layer 62 irradiated by the electron beam 64.

Since the electron beam 64 does not irradiate the portion of the polymer layer 62 between predetermined regions 66 arranged in the array manner, several transparent regions 56 are formed between the phase-shifting patterns 68 after the developing process. Further, the phase-shifting patterns 68 form a plurality of line-shaped features 54 and a plurality of line-shaped features 58 positioned between the line-shaped features 54. Preferably, the longitudinal pitch (space) between the phase-shifting patterns 68 is smaller than the longitudinal width of the phase-shifting pattern 68, i.e., the longitudinal width of the phase-shifting pattern 66 is larger than the longitudinal width of the transparent region 56. The latitude pitch between the line-shaped features 54 is equal to the latitude width of the line-shaped features 54, i.e., the width of the line-shaped features 54 and 58 are the same. In addition, the substrate 52 can be a quartz substrate, or a quartz substrate with an interface layer (not shown in the figure) positioned on the surface of the substrate 52, wherein the interface layer can be a conductive layer made of conductive polymer such as cis-polystyrene and polyaniline, or a glue layer made of hexamethyldisilazane.

The polymer layer 62 may include silsesquioxane. For example, the silsesquioxane can be hydrogen silsesqnioxane (HSQ), and a developing process using alkaline solution can be performed to remove the polymer layer 62 not irradiated by the electron beam 64, wherein the alkaline solution is selected from the group consisting of sodium hydroxide (NaOH) solution, potassium hydroxide (KOH) solution, and tetramethylamomnium hydroxide (TMAH) solution. Alternatively, the silsesquioxane can be methylsilsesquioxane (MSQ), and a developing process using an alcohol solution such as an ethanol solution is performed to remove the polymer layer 62 not irradiated by the electron beam 64. Further, the polymer layer 62 can include hybrid organic siloxane polymer (HOSP), and a developing process using a propyl acetate solution is performed to remove the polymer layer 62 not irradiated by the electron beam 64. The irradiation of the electron beam 64 will change the molecular structure of the polymer layer 62, for example, the molecular structure of hydrogen silsesqnioxane will transform into a network with a cage-like structure and the polymer layer 62 will form a bonding with the substrate 52. As a result, it is possible to selectively remove the polymer layer 62 outside the predetermined region 66 by a developing process using the alkaline solution.

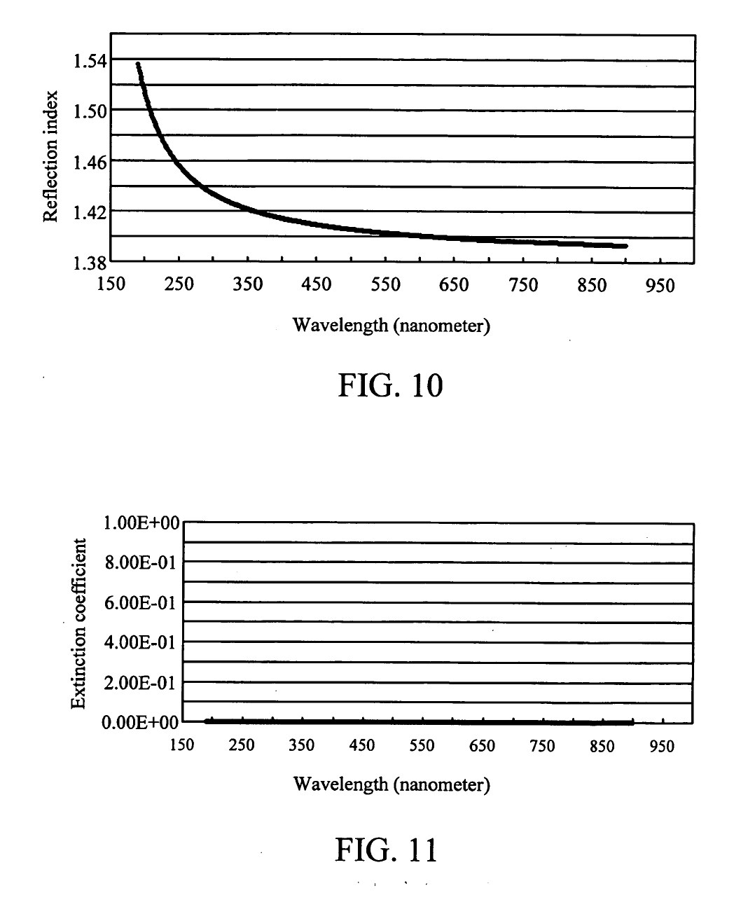

FIG. 10 is a diagram showing the variation of the reflection index of the phase-shifting pattern 68 under different wavelengths according to the present invention. According to known phase-shifting formula: P=2π(n−1)d/mλ, where P represents phase-shifting angle, n represents the reflection index, and λ represents the wavelength of the exposure beam. When the wavelength of the exposure beam is set to 193 nanometers, the corresponding reflection index is about 1.52, and the thickness of the phase-shifting pattern 68 calculated according to the phase-shifting formula should be 1828 angstroms. If the limits of the phase-shifting angle are set to between 177 and 183 degrees, the thickness of the phase-shifting pattern 68 should be between 1797 and 1858 angstroms. When the wavelength of the exposure beam is set to 248 nanometers, the corresponding reflection index is about 1.45, and the thickness of the phase-shifting pattern 68 calculated according to the phase-shifting formula should be 2713 angstroms. If the limits of the phase-shifting angle are set to between 177 and 183 degrees, the thickness of the phase-shifting pattern 68 should be between 2668 and 2759 angstroms.

FIG. 11 is a diagram showing the variation of the extinction coefficient of the phase-shifting pattern 68 under different wavelengths according to the present invention. The extinction coefficient of the polymer layer 62 after the irradiation of the electron beam 64 is substantially zero as the wavelength of the exposure light is between 190 and 900 nanometers. Therefore, after the irradiation of the electron beam 64, the polymer layer 62 becomes a transparent layer capable of lagging the phase angle of a penetrating light, which can be applied to the preparation of the phase-shifting mask.

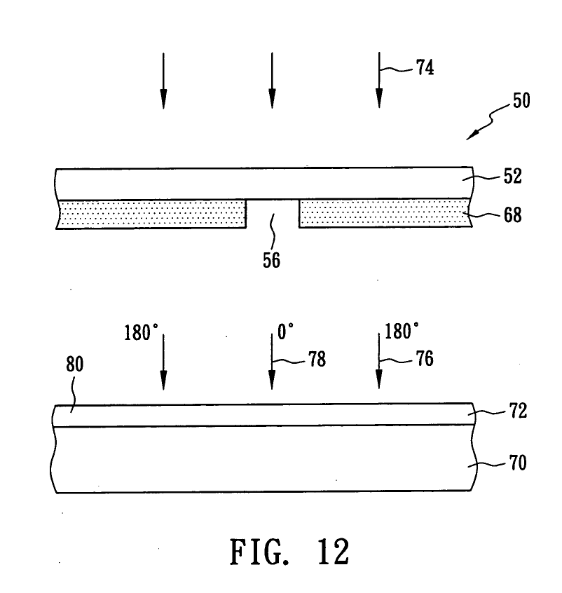

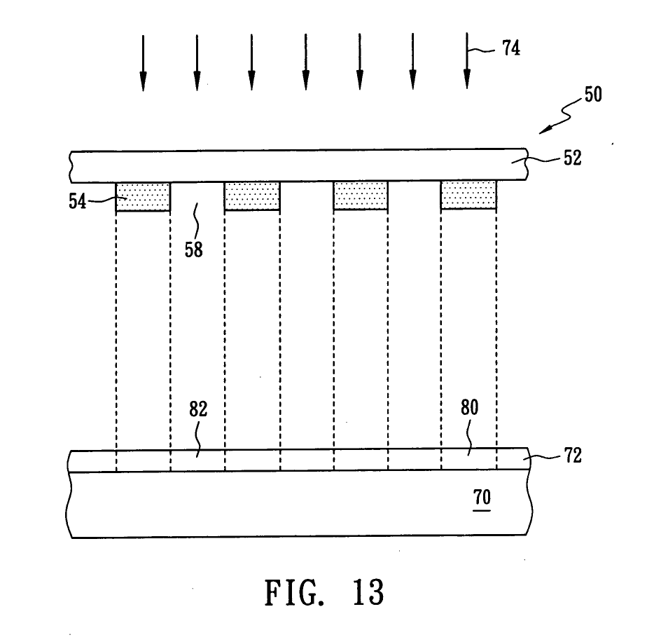

FIG. 12 and FIG. 13 are schematic diagrams showing the application of the phase-shifting mask 50 to the patterning of a semiconductor device such as a gate electrode or a conductive layer of a transistor on a semiconductor substrate 70 according to one embodiment of the present invention, wherein FIG. 12 is a cross-sectional diagram along the A-A cross-section line in FIG. 9, while FIG. 13 is a cross-sectional diagram along B-B cross-sectional line in FIG. 9. The lateral width of the line-shaped feature 58 (zero degree region) is substantially the same as the lateral width of the line-shaped feature 54 (180 degree phase-shifting region), i.e., line width: space width is 1:1. The thickness of the phase-shifting pattern 68 is so designed that the phase angle of a penetrating light 76 lags by 180 degrees after an exposure light 74 penetrates the phase-shifting pattern 68, while the phase angle of a penetrating light 78 is maintained at zero degrees without lagging after the exposure light 74 penetrates the transparent region 56. Consequently, the zero-order beam of the penetrating light 76 interferes destructively with the zero-order beam of the penetrating light 78, and the line-shaped region 80 in the photoresist layer 72 right below the line-shaped region 54 cannot be exposed. In other words, the exposure light 74 cannot expose the line-shaped regions 80 in the photoresist layer 72 right below the line-shaped feature 54 consisting of the phase-shifting patterns 68 on the phase-shifting mask 50, but can expose the line-shaped regions 82 right below the transparent line-shaped feature 58 only.

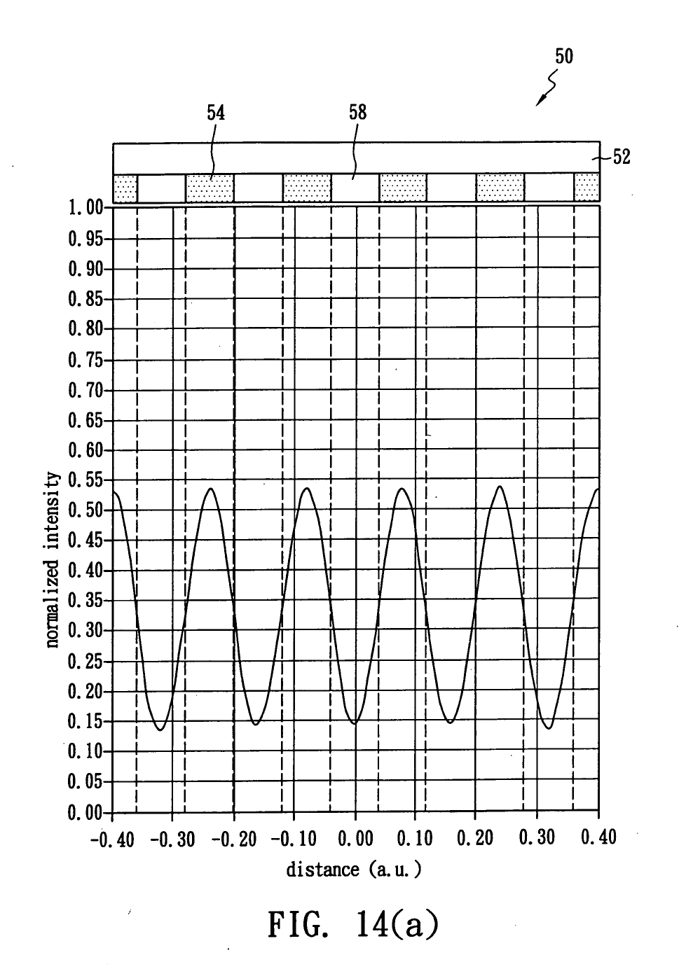

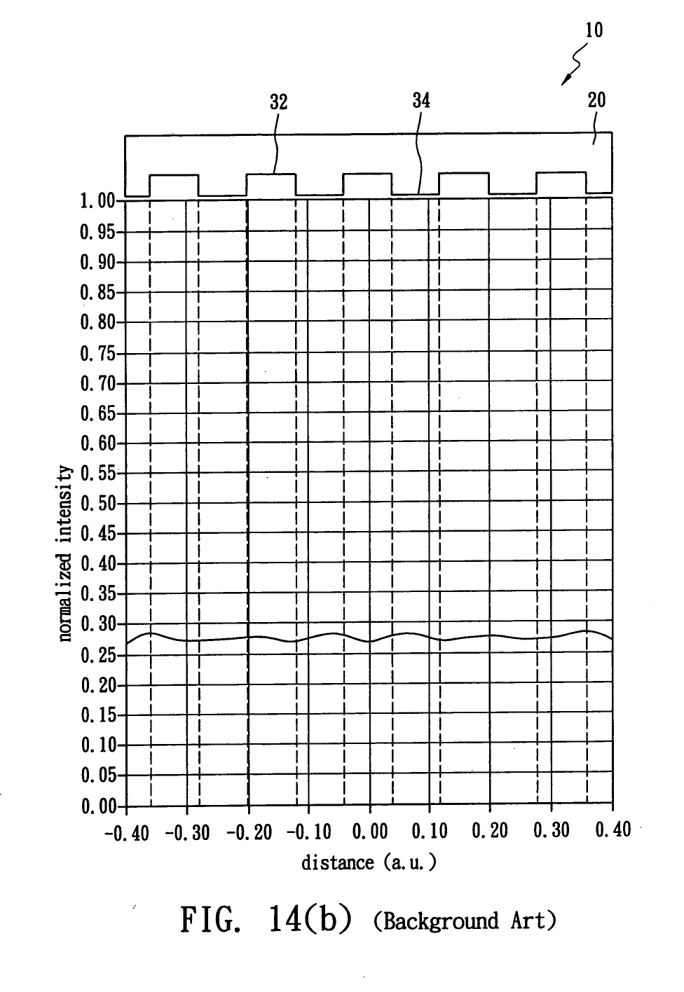

FIG. 14(a) shows the intensity distribution of an aerial image after the exposure light 74 penetrates through the chromeless phase-shifting mask 50 according to the present invention, which is calculated from an optic simulation software called SOLID E. If the critical sensitivity of the photoresist layer 72 is set to 0.3, line-shaped patterns with equal width and pitch can be formed in the photoresist layer 72 on the semiconductor substrate 70 by the chromeless phase-shifting mask 50 incorporating the OAI system. Referring back to FIG. 9, there is 180 degrees of phase difference between light penetrating the line-shaped feature 54 and light penetrating the transparent region 56, and the optical simulation software can be used to determine the shape and size of the transparent region 56. As to the OAI system, the zero-order diffraction beam of the penetrating light 76 and the zero-order diffraction beam of the penetrating light 78 will not cancel out, but rather will interfere to form an image.

In addition, when the chromeless phase-shifting mask 50 including a layout with equal line width and space width is applied to the OAI system, the zero-order beam of the penetrating light 78 through the transparent region 56 interferes destructively with the zero-order beam of the penetrating light 76 through the phase-shifting pattern 68 since there is 180 degrees of phase difference, and the zero-order beam of the penetrating light 76 with 180 degrees of phase lag through the phase-shifting pattern 68 also interferes destructively with the zero-order beam of the penetrating light 78 without phase lag through the line-shaped feature 58. In other words, the zero-order beam of the penetrating light 78 with 180 degrees of phase lag after penetrating through the phase-shifting pattern 68 is canceled out completely and can not generate any image by interference, while the zero-order beam of the penetrating light 78 without phase lag after penetrating through the line-shaped feature 58 is only partially cancelled out and possesses an intensity substantially the same as the intensities of the positive first-order (+1) beam and negative first-order (−1) beam, which is contributive to enhance the intensity difference between the line-shaped region 80 and the line-shaped region 82 in the photoresist layer 72, i.e., to enhance the contrast. On the contrary, when the conventional chromeless phase-shifting mask 10 (shown in FIG. 6) including a layout with equal line width and space width is applied to the OAI system, the intensity difference of the aerial image is too small to generate an image on the photoresist layer 72, as shown in FIG. 14(b).

Particularly, the thickness of the substrate 52 right below the phase-shifting pattern 68 is the same as that right below the transparent region 56 since the chromeless phase-shifting mask 50 is prepared without etching the substrate 52 according to the embodiment of the present invention. In other words, when the exposure light 74 penetrates through the transparent region 56 and the phase-shifting pattern 68, it penetrates the same thickness of substrate 52, so the difference of the irradiation intensity of the exposure light 74 between the line-shaped region 80 and the line-shaped region 82 is originated from the phase-shifting pattern 68 only. That is, the value of the phase angle of the chromeless phase-shifting mask 50 depends primarily on the thickness of the phase-shifting pattern 68, and is irrelevant to the thickness of the substrate 52.

Further, the chromeless phase-shifting mask 50 has a quartz substrate 50 with a uniform thickness, the exposure light 74 propagates through the same distance in the substrate 52, and therefore the present invention can eliminate the phase error problem and the intensity imbalance problem originating from the etching processes on the quartz substrate according to the prior art. In addition, the polymer layer 62 can be formed on the substrate 52 by the spin-coating process, which can precisely control the thickness of the polymer layer 62, i.e., precisely control the thickness of the phase-shifting pattern 68 and the phase-shifting angle.

Particularly, the polymer layer 62 includes silsesquioxane or hybrid organic siloxane polymer, whose molecular structure and chemical properties such as solubility will be changed by the irradiation of the electron beam 64 and an alkaline solution can be used to selectively remove a portion of the polymer layer 62. Since the electron beam 74 possesses a very small diameter to irradiate only a very small region of the polymer layer 62, the present invention can precisely control the lateral width of the phase-shifting pattern 68.

Compared to the prior art, the present invention can increase mask throughput, eliminate phase error problems and mask inspection issues, and solve the imaging problem of the OAI technique in cases where masks have equal line width and space width. The prior art needs to perform the lithographic process twice, which increases alignment difficulty and restricts mask throughput. On the contrary, the present method is simpler since the phase-shifting pattern is prepared by the integration of the coating (or deposition) technique, the electron beam exposure technique and the lithographic process, so mask throughput can be increased. Further, the present method does not need to perform the lithographic process twice to prepare the phase-shifting pattern, so there are no alignment issues. In addition, the prior art prepares the phase-shifting pattern by etching the quartz substrate, which generates mask inspection and phase error issues. On the contrary, the present method prepares the phase-shifting pattern without etching the substrate, so phase error problems and mask inspection issues can be eliminated. Particularly, the present invention can solve the imaging problem of the OAI system in cases where phase-shifting masks have equal line width and space width, i.e., line width: space width is 1:1, and increase the contrast of patterns.

The above-described embodiments of the present invention are intended to be illustrative only. Numerous alternative embodiments may be devised by those skilled in the art without departing from the scope of the following claims.

What is claimed is:

1. A method for preparing a phase-shifting mask, comprising steps of:
forming a polymer layer on a substrate;
changing the molecular structure of the polymer layer in a plurality of predetermined regions, wherein each of the predetermined regions has a first width larger than a first space between the predetermined regions along a first direction; and
removing a portion of the polymer layer outside the predetermined regions to form a plurality of phase-shifting patterns.

2. The method for preparing a phase-shifting mask of claim 1, wherein the polymer layer is formed on the substrate by a spin-coating process.

3. The method for preparing a phase-shifting mask of claim 1, wherein the polymer layer includes silsesquioxane.

4. The method for preparing a phase-shifting mask of claim 3, wherein the silsesquioxane is hydrogen silsesquioxane.

5. The method for preparing a phase-shifting mask of claim 4, wherein the portion of the polymer layer outside the predetermined regions is removed by using an alkaline solution.

6. The method for preparing a phase-shifting mask of claim 5, wherein the alkaline solution is selected from the group consisting of sodium hydroxide, potassium hydroxide, and tetramethylamomnium hydroxide.

7. The method for preparing a phase-shifting mask of claim 3, wherein the silsesquioxane is methylsilsesquioxane.

8. The method for preparing a phase-shifting mask of claim 7, wherein the portion of the polymer layer outside the predetermined regions is removed by using an alcohol solution.

9. The method for preparing a phase-shifting mask of claim 8, wherein the alcohol solution is an ethanol solution.

10. The method for preparing a phase-shifting mask of claim 1, wherein the polymer layer includes hybrid organic siloxane polymer.

11. The method for preparing a phase-shifting mask of claim 10, wherein the portion of the polymer layer outside the predetermined regions is removed by using a propyl acetate solution.

12. The method for preparing a phase-shifting mask of claim 1, wherein the plurality of predetermined regions are arranged in an array manner.

13. The method for preparing a phase-shifting mask of claim 1, wherein the plurality of predetermined regions form a plurality of line-shaped features.

14. The method for preparing a phase-shifting mask of claim 13, wherein the line-shaped feature has a second width substantially equal to a second space between the line-shaped features along a second direction perpendicular to the first direction.

15. The method for preparing a phase-shifting mask of claim 1, wherein the substrate is made of quartz.

16. The method for preparing a phase-shifting mask of claim 1, wherein the substrate comprises a quartz substrate and an interface layer positioned on the surface of the quartz substrate.

17. The method for preparing a phase-shifting mask of claim 16, wherein the interface layer is a conductive layer or a glue layer.

18. The method for preparing a phase-shifting mask of claim 1, wherein the molecular structure of the polymer layer in a plurality of predetermined regions is changed by irradiating an electron beam on the predetermined regions.

19. The method for preparing a phase-shifting mask of claim 1, wherein the molecular structure of the polymer layer in a plurality of predetermined regions is changed by providing energy to the predetermined regions.

20. A method for preparing a semiconductor device, comprising steps of:
forming a photoresist layer on a first substrate;
exposing the photoresist layer by a phase-shifting mask including a second substrate and a plurality of phase-shifting patterns positioned on the second substrate, wherein each of phase-shifting patterns includes a polymer material and has a first width larger than a first space between the phase-shifting patterns along a first direction; and
developing the photoresist layer.

21. The method for preparing a semiconductor device of claim 20, wherein the polymer material is silsesquioxane.

22. The method for preparing a semiconductor device of claim 21, wherein the silsesquioxane is hydrogen silsesquioxane.

23. The method for preparing a semiconductor device of claim 21, wherein the silsesquioxane is methylsilsesquioxane.

24. The method for preparing a semiconductor device of claim 20, wherein the polymer material is hybrid organic siloxane polymer.

25. The method for preparing a semiconductor device of claim 20, wherein the phase-shifting patterns are arranged in an array manner.

26. The method for preparing a semiconductor device of claim 20, wherein the phase-shifting patterns form a plurality of line-shaped features.

27. The method for preparing a semiconductor device of claim 27, wherein the line-shaped feature has a second width substantially equal to a second space between the line-shaped features along a second direction substantially perpendicular to the first direction.
